(19) United States
(12) Patent Application Publication
(10) Pub. No.: US 2010/0259134 A1
(43) Pub. Date: Oct. 14, 2010

(54) Piezoelectric Actuator having Externally Contacted Inner Electrodes of a Piezoelectric Element

(76) Inventors: Eugen Hohmann, Viereth-Trunstadt (DE); Immanuel Fergen, Bruchsal (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/295,799

(22) PCT Filed: Apr. 17, 2007
(86) PCT No.: PCT/EP2007/053719

§ 371 Date: May 17, 2010

(30) Foreign Application Priority Data
Apr. 19, 2006 (DE) 102006018056.9

(51) Int. Cl. H01L 41/047; H01L 41/22; H01L 41/083

(52) U.S. Cl. 310/366; 29/25.35

(57) ABSTRACT

The invention relates to a piezoelectric actuator having a multi-layered structure of piezo-layers in a piezo element and inner electrodes that are arranged between the piezo-layers. The electrodes are alternatively supplied with an electric voltage of a different polarity in the direction of the layer structure of the piezoelectric element. The alternate lateral contacting of the inner electrodes is achieved via outer electrodes and/or a baked base metallic coating of the lateral surfaces. The respective outer electrodes include a bending coil which is wound from a contactable material. During baking of the base metallic coating the contactable material is applied together with at least parts of the bending coil to the coating in a conductive manner. A flexible sheet metal part that has first been provided with cut sections and/or pre-stamped sections can also be used as an outer electrode.

The invention relates to a piezoelectric actuator, for instance for actuating a mechanical component, such as a valve or the like, with externally contacted inner electrodes of a piezoelectric element, in accordance with the characteristics of the preamble to the coordinate main claims.

### PRIOR ART

It is known per se that for constructing the aforementioned piezoelectric actuator, a piezoelectric element can be used in such a way that by utilizing what is known as the piezoelectric effect, the needle stroke of a valve or the like can be controlled. The piezoelectric element is constructed of a material with a suitable crystalline structure such that upon application of an external electrical voltage, a mechanical reaction of the piezoelectric element ensues, which depending on the crystalline structure and the regions where the electrical voltage is applied represents compression or tension in a predeterminable direction. Such piezoelectric actuators are suitable for instance for applications in which reciprocating motions take place under strong actuation forces and at high pulse frequencies.

For instance, one such piezoelectric actuator is known as a component of a piezoelectric injector from German Patent Disclosure DE 10026005 A1, which can be used to trigger the nozzle needle in injectors for injecting fuel into the combustion chamber of an internal combustion engine. In this piezoelectric actuator, a piezoelectric element is constructed as a stack of a plurality of electrically coupled-together piezoceramic layers, and this stack is held between two stops by prestressing. Each piezoceramic layer is fixed between two inner electrodes, by way of which an electrical voltage can be applied from outside. Because of this electrical voltage, the piezoceramic layers then each execute short reciprocating motions in the direction of the potential drop, and these motions add together to make the total stroke of the piezoelectric actuator. This total stroke is variable by way of the level of the voltage applied and can be transmitted to a mechanical final control element.

In the aforementioned piezoelectric actuator, to bring about the different potentials, an alternating lateral contacting of the inner electrodes is done via outer electrodes, and in this process conductive surfaces are applied to each side face of the piezoelectric element and are contacted with the various inner electrodes.

Upon an actuation of the piezoelectric actuator, different mechanical forces occur both in the region of the inner electrodes and in the region of the contact points at the outer electrodes, and these can cause mechanical stresses and hence cracks in the outer electrodes. The outer electrodes then have to be provided again with terminal electrodes, which have to be extended farther outward and as a rule must also withstand mechanical stresses.

In German Patent Disclosure DE 19928190 A1, a piezoelectric actuator is described in which to attain a certain flexibility, at least one layer of the respective outer electrode is constructed in netlike, sievelike or clothlike fashion, each distributed over one side face, and is contacted at least at some points to the respective inner electrodes. It is furthermore known from German Patent Disclosure DE 1998178 A1 that a piezoelectric actuator of this kind can be provided with metal foils as components of the outer electrodes, which at least in the region of neutral layers in the construction of the piezoelectric element have compensatory waves.

The external contacting can be done in the known piezoelectric actuators in double layers, for instance with a coated sieve, and during the attachment by means of a soldering process, all the nodes in the weave of the sieve are firmly clamped and bound with solder. The aforementioned desired movability of the sieve cloth is as a rule sharply reduced, however, in that case and can be utilized to only a limited extent.

### DISCLOSURE OF THE INVENTION

The invention is based on a piezoelectric actuator as described at the outset, which is provided with a multilayer construction of piezoelectric layers in a piezoelectric element and with inner electrodes disposed between the piezoelectric layers. The inner electrodes are subjected in the direction of the layer construction of the piezoelectric element with a different polarity of an electrical voltage in alternation, via an alternating lateral contacting. The outer electrodes comprise at least one fired base metallization of the side faces. According to the invention, in a first embodiment, each outer electrode advantageously has a flexible coil, which is wound for instance from a conductive material and is applied conductively to the base metallization, with at least parts of the coil, during the firing of the base metallization.

The flexible coil may be upset in the winding cross section and can be provided, on the side diametrically opposite the base metallization, with a reinforcement strip of a conductive material, which is then optionally also contactable to connection lines.

In a second embodiment, each outer electrode is a flexible sheet-metal part, which is provided with cutout features and/or prestamped features and which in the firing of the base metallization is applied with at least parts of its structure conductively to the base metallization.

The flexible sheet-metal part can be broken open in its structure to produce the flexibility by means of cutting and/or stamping, and the cutout features and/or cutouts can be enlarged further by drawing in the direction of the two-dimensional extent before being applied to the base metallization.

On the other hand, the flexible sheet-metal part can be broken open in its structure to produce the flexibility by means of cutting and/or stamping, and the cutout features and/or cutouts, for contacting to the base metallization, are bent out of the bottom face before the application to the base metallization.

In all the embodiments, the coil or the sheet-metal part can be made either from a metal or from a material provided with a conductive coating.

A piezoelectric actuator according to the invention, in a simple production process, can be ground on the sides after a sintering process, and then base metallizing is done with placement of the coil or the sheet-metal part on top. The firing of the base metallization with the coil or the sheet-metal part is then done before a so-called hot or frequency polarization and a concluding immersion coating of the piezoelectric element or the piezoelectric actuator.

In summary, with the piezoelectric actuator of the invention, above all a secure, durable external contacting of the inner electrodes of the piezoelectric element can thus be achieved. The movements inside the piezoelectric element that are caused by the actuation of the piezoelectric actuator lead to different motions in three axes. In the primary direction of motion or actuation (Z axis), such a piezoelectric actuator expands by approximately 100-120 μm, for instance; conversely, in the X and Y axes, it shrinks by approximately 40-50 μm.

For this reason, for instance in the prior art mentioned at the outset, the external contacting is done with a coated double-layer sieve. The electrical attachment is then done in the prior art by means of a soldering process, in which all the nodes of the weave of the sieve are firmly clamped and bound with solder, restricting the movability.

With the embodiments according to the invention, an external attachment, which can be produced economically, of the inner electrodes is created, which meets the aforementioned demands in terms of movement and the required capability of expanding in the three axial directions, for instance during a transit time of 10⁹ load cycles of the piezoelectric actuator. Moreover, replicable conditions for further economical, process-safe assembly attachments, for instance of an actuator foot, are created by gap welding. The previously required work step of soldering is dispensed with entirely, since attaching the outer electrodes is effected directly with the firing of the base metallization on the piezoelectric actuator, or in other words is effected with direct process coupling.

### BRIEF DESCRIPTION OF THE DRAWINGS

Exemplary embodiments of the piezoelectric actuator of the invention are described in conjunction with the drawings.

FIG. 1 shows a section through a piezoelectric actuator with a multilayer construction of piezoelectric layers and inner electrodes and with a sievelike outer electrode in accordance with the prior art;

FIG. 2a is a detailed view of a portion of a side face of a piezoelectric actuator, with a schematically shown external contacting according to the invention;

FIG. 2b is a view of a first exemplary embodiment of the external contacting of FIG. 2a, with a flexible coil;

FIG. 2c is a side view on the flexible coil of FIG. 2b;

FIGS. 3a and 3b show a different version of the external contact point, with a sheet-metal part with stamped features, before a drawing operation (FIG. 3a) and after the drawing operation (FIG. 3b);

FIG. 3c shows the application of the external contact point of FIG. 3b to the base metallization of the piezoelectric actuator;

FIG. 4a shows a further version of the external contacting, with a sheet-metal part with stamped features;

FIG. 4b shows a view of structures bent out of the sheet-metal part of FIG. 4a; and

FIG. 4c is a side view of the sheet-metal part, applied to the base metallization of the piezoelectric actuator, of FIGS. 4a and 4b.

### EMBODIMENTS OF THE INVENTION

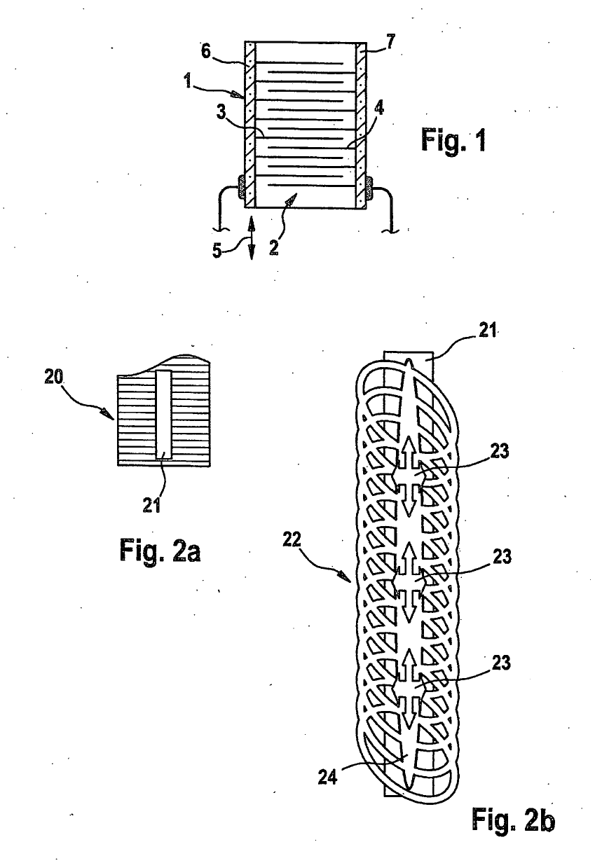

In FIG. 1, a piezoelectric actuator 1, known for instance from the prior art cited at the outset in DE 19928190 A1, is shown, which has a piezoelectric element 2 comprising piezoelectric layers or piezoelectric foils or films, which by utilization of the piezoelectric effect upon application of an electrical voltage to inner electrodes 3 and 4 cause a mechanical reaction of the piezoelectric actuator 1 in the axial direction (arrow 5).

The inner electrodes 3 and 4 are subjected in alternation, in the direction of the layer construction of the piezoelectric element 2, to a different polarity of an electrical voltage. This is achieved by means of an alternating lateral contacting of the inner electrodes 3 and 4 via netlike or sievelike outer electrodes 6 and 7, by way of which the electrical voltage can be supplied; as a rule, the outer electrodes 6 and 7 comprise at least one fired base metallization of the side faces of the piezoelectric actuator 1, onto which base metallization the netlike or sievelike outer electrodes 6 and 7 are soldered, in the piezoelectric actuator 1 known from the prior art. The piezoelectric actuator 1 can then be embedded solidly in a housing, via a foot and/or head part not shown here, such as the housing of an injection valve for motor vehicles for controlling the valve, and can thus be a component of a so-called piezoelectric injector.

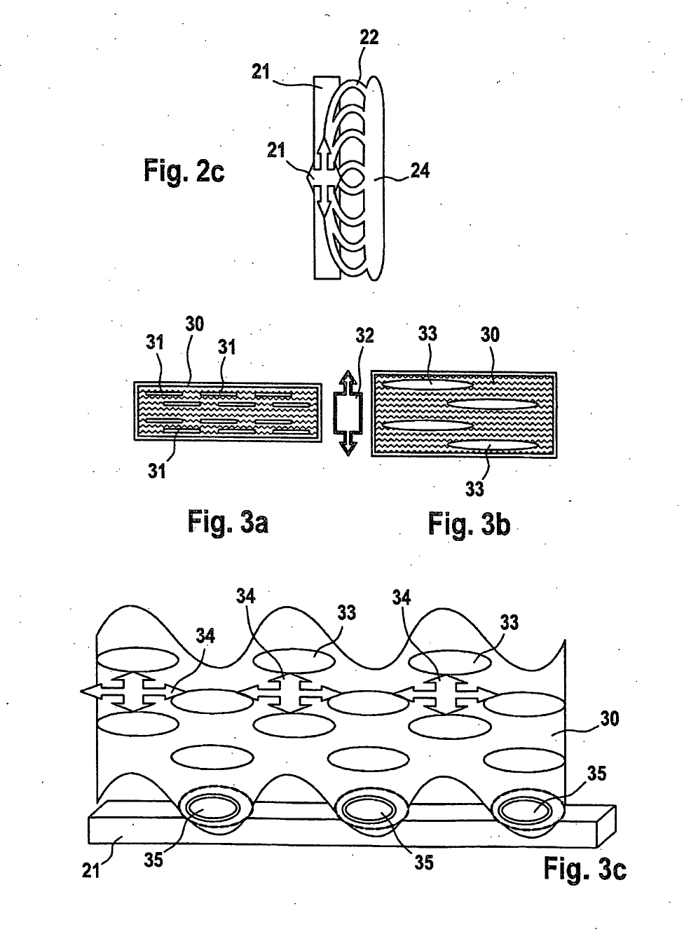

A first exemplary embodiment of the invention will now be explained in conjunction with FIGS. 2a, 2b and 2c. In FIG. 2a, a part of the side face of a piezoelectric actuator 20 of the invention is shown, on which a layer 21 for an outer electrode is applied, for contacting the inner electrodes shown here only schematically. The layer 21 has been fired jointly in place during the base metallizing of the side face.

From FIG. 2b, the exemplary embodiment of an outer electrode, which comprises a so-called flexible coil 22, can be seen. The windings of the flexible coil 22 here are also contacted with the piezoelectric actuator 20 during the firing of the layer 21 and the base metallization, and because of their clearances of motion, represented by arrows 23, they provide secure contacting even in the case of the motions, mentioned in the general description, of the piezoelectric actuator 20 in the three axes. A reinforcement strip 24 is present here as well, which can be upset in height. From FIG. 2c, a side view can also be seen on the arrangement of FIG. 2b.

In FIGS. 3a, 3b and 3c, another exemplary embodiment of the invention is shown, with an outer electrode shaped from a sheet-metal part 30. In the sheet-metal part 30, cutout features 31 are first made, which as indicated by the arrow 32, by drawing in the direction shown, are made into relatively large free spaces 33, which are then likewise capable of compensating for the motions (see arrows 34 in FIG. 3c) of the piezoelectric actuator 20 in the three axes. In the lower region, the contact points 35 with the layer 21 and with the base metallization can be seen.

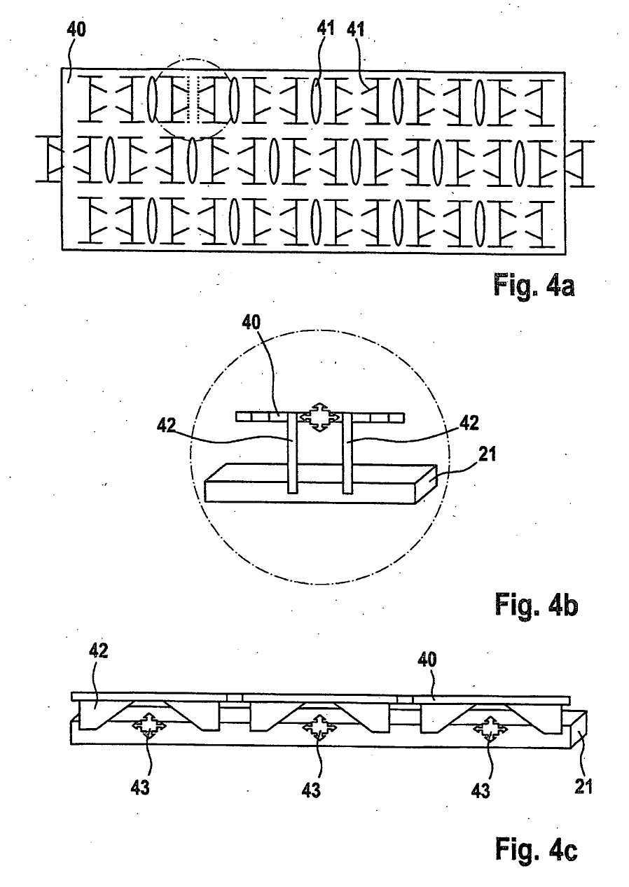

A further exemplary embodiment is shown in FIGS. 4a, 4b and 4c; in it, once again, a sheet-metal part 40 is assumed as the starting element for the outer electrode. Once again, there are cutout features 41, which are designed by drawing to make relatively large free spaces. From FIG. 4b, elements 42 that are also bent outward can be seen in detail, with which elements the contact points with the layer 21 and with the base metallization are made.

From FIG. 4c, a side view can also be seen on the arrangement of FIG. 4b, from which it can be seen how here as well, the motions in accordance with the arrows 43 of the piezoelectric actuator 20 in the three axes are assured.

1-8. (canceled)

9. A piezoelectric actuator, comprising:
a multilayer construction of piezoelectric layers in a piezoelectric element;
inner electrodes disposed between the piezoelectric layers, the inner electrodes being subjected in alternation, in the direction of the layer construction of the piezoelectric element, with a different polarity of an electrical voltage;
outer electrodes disposed in alternating lateral contact with the inner electrodes, through which the electrical voltage is delivered to the inner electrodes, wherein the outer electrodes comprise at least one fired base metallization of side faces of the piezoelectric actuator, and wherein each outer electrode has a flexible coil, which is wound from a contactable material, and in firing of the base metallization, at least some parts of the flexible coil are applied conductively to the base metallization.

10. The piezoelectric actuator as defined by claim 9, wherein the flexible coil is upset in the winding cross section.

11. The piezoelectric actuator as defined by claim 9, wherein the flexible coil is provided, on a side diametrically opposite the base metallization, with a reinforcement strip comprising a conductive material.

12. The piezoelectric actuator as defined by claim 10, wherein the flexible coil is provided, on a side diametrically opposite the base metallization, with a reinforcement strip comprising a conductive material.

13. The piezoelectric actuator as defined by claim 9, wherein the flexible coil is produced from a material provided with a conductive coating.

14. The piezoelectric actuator as defined by claim 10, wherein the flexible coil is produced from a material provided with a conductive coating.

15. The piezoelectric actuator as defined by claim 12, wherein the flexible coil is produced from a material provided with a conductive coating.

16. A method for producing a piezoelectric actuator as defined by claim 9, comprising the steps of:
performing a sintering process to the piezoelectric element;
grinding the piezoelectric elements on its sides;
performing a base metalizing by placement of the flexible coil on top of the sides;
performing a firing of the base metallization with the flexible coil;
effecting a hot polarization; and
immersion coating the piezoelectric actuator.

17. A method for producing a piezoelectric actuator as defined by claim 10, comprising the steps of:
performing a sintering process to the piezoelectric element;
grinding the piezoelectric elements on its sides;
performing a base metalizing by placement of the flexible coil on top of the sides;
performing a firing of the base metallization with the flexible coil;
effecting a hot polarization; and
immersion coating the piezoelectric actuator.

18. A method for producing a piezoelectric actuator as defined by claim 15, comprising the steps of:
performing a sintering process to the piezoelectric element;
grinding the piezoelectric elements on its sides;
performing a base metalizing by placement of the flexible coil on top of the sides;
performing a firing of the base metallization with the flexible coil;
effecting a hot polarization; and
immersion coating the piezoelectric actuator.

19. A piezoelectric actuator, comprising:
a multilayer construction of piezoelectric layers in a piezoelectric element;
inner electrodes disposed between the piezoelectric layers, the inner electrodes being subjected in alternation, in the direction of the layer construction of the piezoelectric element, with a different polarity of an electrical voltage; outer electrodes disposed in alternating lateral contact with the inner electrodes, through which the electrical voltage is delivered to the inner electrodes, wherein the outer electrodes comprise at least one fired base metallization of side faces of the piezoelectric actuator, and wherein each outer electrode is a flexible sheet-metal part, which is provided with cutout features and/or prestamped features, and in firing of the base metallization, at least some parts of the flexible sheet-metal part are applied conductively to the base metallization.

20. The piezoelectric actuator as defined by claim 19, characterized in that the flexible sheet-metal part is broken open in its structure to produce the flexibility by means of cutting and/or stamping therein, and the cutout features produced by the cutting and/or stamping are enlarged by drawing out of the sheet-metal part before being applied to the base metallization.

21. The piezoelectric actuator as defined by claim 19, wherein the flexible sheet-metal part is broken open in its structure to produce the flexibility by means of cutting and/or stamping, and cutout features, for contacting with the base metallization, are bent out of a bottom face before the application to the base metallization.

22. The piezoelectric actuator as defined by claim 19, wherein the flexible sheet-metal part is produced from a material provided with a conductive coating.

23. The piezoelectric actuator as defined by claim 20, wherein the flexible sheet-metal part is produced from a material provided with a conductive coating.

24. The piezoelectric actuator as defined by claim 21, wherein the flexible sheet-metal part is produced from a material provided with a conductive coating.

25. A method for producing a piezoelectric actuator as defined by claim 19, comprising the steps of:
performing a sintering process to the piezoelectric element;
grinding the piezoelectric elements on its sides;
performing a base metalizing by placement of the flexible sheet-metal part on top of the sides;
performing a firing of the base metallization with the flexible sheet-metal part;
effecting a hot polarization; and
immersion coating the piezoelectric actuator.

26. A method for producing a piezoelectric actuator as defined by claim 20, comprising the steps of:
performing a sintering process to the piezoelectric element;
grinding the piezoelectric elements on its sides;
performing a base metalizing by placement of the flexible sheet-metal part on top of the sides;
performing a firing of the base metallization with the flexible sheet-metal part;
effecting a hot polarization; and
immersion coating the piezoelectric actuator.

27. A method for producing a piezoelectric actuator as defined by claim 21, comprising the steps of:
performing a sintering process to the piezoelectric element;
grinding the piezoelectric elements on its sides;
performing a base metalizing by placement of the flexible sheet-metal part on top of the sides;
performing a firing of the base metallization with the flexible sheet-metal part;
effecting a hot polarization; and
immersion coating the piezoelectric actuator.

28. A method for producing a piezoelectric actuator as defined by claim 22, comprising the steps of:
performing a sintering process to the piezoelectric element;
grinding the piezoelectric elements on its sides;
performing a base metalizing by placement of the flexible sheet-metal part on top of the sides;
performing a firing of the base metallization with the flexible sheet-metal part;
effecting a hot polarization; and
immersion coating the piezoelectric actuator.
